(19) United States
(12) Patent Application Publication
(10) Pub. No.: US 2017/0092355 A1
(43) Pub. Date: Mar. 30, 2017

(54) SEMICONDUCTOR STORAGE DEVICE

(71) Applicant: HITACHI, LTD., Chiyoda-ku, Tokyo (JP)

(72) Inventors: Kenzo KUROTSUCHI, Tokyo (JP); Yoshitaka SASAGO, Tokyo (JP); Satoru HANZAWA, Tokyo (JP)

(21) Appl. No.: 15/122,905

(22) PCT Filed: Mar. 19, 2014
(86) PCT No.: PCT/JP2014/057438

§ 371 Date: Aug. 31, 2016

(51) Int. Cl. G11C 13/00

(52) U.S. Cl. CPC G11C 13/0069; G11C 13/0004; G11C 13/003; G11C 2213/72; G11C 2213/79

(57) ABSTRACT

It is possible to realize a highly reliable semiconductor storage device using the semiconductor storage device which includes a plurality of memory chains including a plurality of memory cells connected in series and in which the memory cell is a storage element that performs rewrite using a cell transistor and current, the memory chain has a structure in which the storage elements are connected in parallel, a power-supply voltage and a ground voltage are supplied from an outside, and a voltage to be used for the rewrite of the storage element is lower than the ground voltage, and further, it is possible to realize the semiconductor storage device that has a large capacity, is capable of high-speed read and write, and can be manufactured with low cost.

### TECHNICAL FIELD

The present invention relates to a semiconductor storage device that includes a rewritable non-volatile memory, for example, a phase change memory, a ReRAM, or an STT-MRAM, or a technique which is advantageous when being applied to a storage system that includes the semiconductor storage device.

### BACKGROUND ART

A technique in which a phase change memory is used as a non-volatile memory, and a semiconductor memory device having a large capacity is manufactured by connecting a plurality of bits in series like a chain is known as a background art of the present technical field (for example, see PTL 1). This gazette describes, “there is a problem that characteristics of a transistor deteriorates as carriers go from a diode into the transistor in a semiconductor memory having a diode and a transistor connected in series” (see the Abstract). In addition, paragraph [0044] describes, “for example, the following actions take place in a chain cell, namely a cell in which memory cells, including transistors and phase change elements connected in parallel as mentioned above, are connected in series”.

In addition, there is PTL 2. This gazette describes, “a phase change memory including: a memory cell MC which is configured of a chalcogenide wiring GST, resistance wirings connected to each of both ends of the chalcogenide wiring, and a cell transistor of which a source and a drain are connected with the other ends of the resistance wirings, respectively; a select transistor in which a plurality of the memory cells are connected in series and one end thereof is connected to a source of the select transistor and of which a drain is connected to a bit line; and a memory cell array which is configured by forming a cell string by connecting the other end of the plurality of memory cells connected in series to a source line, connecting a gate of the memory cell to a word line, and connecting a gate of the select transistor to a block select line, and by arranging a plurality of cell strings” (see the Abstract). Further, it is described, as the description of FIG. 6, “FIGS. 5 and 6 illustrate other read/write operation examples”, and “The drawings are different from FIGS. 3 and 4 in that the source line SL is set to VINT and only the selected bit line BL is set to VINT4 lower than VINT to apply the current for reading at the read operation time, and that the source line SL is set to VINT and only the selected bit line BL is set to VINT5 slightly lower than VINT to perform set operation, and set to further lower VINT6 to perform the reset operation at the program operation time” (see paragraph [0030]).

Further, there is PTL 3. This gazette describes, “a memory cell 300 that is obtained by connecting a resistance change device 309, which is configured of a lower electrode 309a, an upper electrode 309c, and a resistance change layer 309b that reversibly changes based on electrical signals having different polarities to be applied between both the electrodes, and a transistor 317 in series is provided, the resistance change layer 309b is formed using an oxide layer made of an oxygen-deficient transition metal, the lower electrode 309a and the upper electrode 309c are configured using materials containing different elements, a standard electrode potential V1 of the lower electrode 309a, a standard electrode potential V2 of the upper electrode 309c, and a standard electrode potential Vt of the transition metal satisfy a relation that Vt<V2 and V1<V2, and a read circuit (not illustrated) applies a read voltage that makes the upper electrode 309c positive while using the lower electrode 309a as a reference via a voltage clamp circuit” (see the Abstract).

### CITATION LIST

### Patent Literature

PTL 1: JPA Laid-Open No. 2012-69830

PTL 2: JPA Laid-Open No. 2012-204404

PTL 3: JPA Laid-Open No. 2010-015662

### SUMMARY OF INVENTION

### Technical Problem

A partial structure of a memory array becomes a chain-like structure (memory chain) in which a memory cell is configured by connecting a storage element and a select element in parallel, and such memory cells are connected in series in a technique of obtaining a larger capacity of a semiconductor storage device using a three-dimensional structure, reducing cost per bit, and rewriting a value of a non-volatile element using current. Gate electrodes of the select elements are shared among a plurality of memory chains, and are electrically connected to each other. The following description is given using the select element as a transistor.

Here, when the current is caused to flow to rewrite the storage element, a voltage drop occurs in the storage element or the select element. Thus, a source potential of the select element increases, and accordingly, it is necessary to increase a potential of a gate electrode of the select element in order to secure a certain amount of voltage between the gate and the source. Then, a potential of a gate electrode of an unselected memory chain, which is electrically connected, increases simultaneously, but the current substantially does not flow into the unselected memory chain, and the voltage drop substantially does not occur so that a voltage between a gate and a source of a select element of the unselected memory chain increases, and the select element is likely to be broken down, thereby generating a problem that the reliability deteriorates.

The example of the semiconductor storage device having the three-dimensional structure will be described in detail with reference to FIG. 4. The transistor and the non-volatile memory are connected in parallel, and a plurality of such groups are connected in series. A memory chain MU has one end being connected to the source electrode without the select element interposed therebetween and the other end being connected to a bit line via a select element XTr. The gate electrodes of Z-select transistors on zeroth layers are connected to each other among the respective memory chains MU, and are controlled to be a potential VZ0. Z-select transistors on a first layer to a seventh layer are configured in the same manner.

FIG. 5 illustrates each potential of the electrodes at the time of write, that is, the time of rewriting values of “0” and “1” of the non-volatile memory. A phase change element PCM1 inside a memory chain MU00 is set as a selected bit. Phase change elements PCM0 and PCM2 to PCM7 are unselected bits. In addition, phase change elements inside memory chains MU01, MU10 and MU11 are set as unselected bits. Since the source electrode is connected to the memory chain MU without the select element interposed therebetween, disturbance occurs in the phase change element PCM inside the memory chain MU when a potential VS of the source electrode is transitioned, and thus, it is desirable that the potential VS of the source electrode be kept to be constant, that is, 0 V. A write current, for example, 40 μA is caused to flow in the phase change element PCM, and thus, a potential VBL-S of the bit line connected to the memory chain is changed from 0 V to 7 V, for example.

At this time, a drain voltage of the select element XTr becomes 7 V. When a description is given by assuming that a voltage between the drain and the source of the MOS in an on-state is 0.5 V, a voltage between the gate and the source thereof is 5 V, a voltage between the gate and the source of the MOS in an off-state is 0 V, and a write voltage of the phase change element is 3 V, a source voltage of the select element XTr becomes 6.5 V, and a gate voltage thereof becomes 11.5 V. A drain voltage of a seventh-layer Z-select transistor ZTr7 of the selected memory chain MU00 becomes 6.5 V, a source voltage thereof becomes 6 V, and a gate voltage thereof becomes 11 V.

Herein, a gate electrode of the seventh-layer Z-select transistor of the selected memory chain MU00 is connected to a gate electrode of a seventh-layer Z-select transistor of the unselected memory chain MU11. Thus, a gate voltage of the seventh-layer Z-select transistor of the unselected memory chain MU11 becomes 11 V. Meanwhile, a source electrode of the Z-select transistor of the unselected memory chain MU11 is connected to a source line via the phase change elements PCM on a zeroth layer to a sixth layer, and thus, a potential thereof becomes equal to the source potential VS, that is, 0 V. Thus, when focusing on the transistor of the unselected chain MU11, the voltage between the gate and the source thereof becomes high such as 11 V. The MOS is broken down in some cases due to occurrence of gate breakdown as a high voltage is applied between the gate and the source. That is, there is a problem that the reliability of the semiconductor storage device 601 deteriorates.

The present invention aims to realize a highly reliable semiconductor storage device, and further, to provide a semiconductor storage device that has a large capacity, enables high-speed read and write, and can be manufactured with low cost.

### Solution to Problem

The present invention employs the configuration described in the Claims in order to obtain the above-described objects.

The present invention includes a plurality of means to solve the above-described problems, and an example thereof is characterized by “a semiconductor storage device including a plurality of memory chains that include a plurality of memory cells connected in series, in which the memory cell is a storage element that performs rewrite using a cell transistor and current, the memory chain has a structure in which the storage elements are connected in parallel, a power-supply voltage and a ground voltage are supplied from an outside, and a voltage to be used for the rewrite of the storage element is lower than the ground voltage”.

### Advantageous Effects of Invention

It is possible to realize a highly reliable semiconductor storage device. In addition, it is possible to realize the semiconductor storage device that has the large capacity, further enables the high-speed read and write, and can be manufactured with the low cost.

### BRIEF DESCRIPTION OF DRAWINGS

FIG. 1 is an example illustrating a partial circuit configuration of a memory array of a semiconductor storage device according to Embodiment 1 of the present invention.

FIG. 2 is an example illustrating a partial write operation of the memory array of the semiconductor storage device according to Embodiment 1 of the present invention.

FIG. 3 is an example illustrating a partial operation of the memory array of the semiconductor storage device according to Embodiment 1 of the present invention.

FIG. 4 is an example illustrating a partial circuit configuration of the memory array.

FIG. 5 is an example illustrating a partial write operation of the memory array.

FIG. 6 is an example of a configuration diagram of the semiconductor storage device according to Embodiment 1 of the present invention.

FIG. 7 is an example of a configuration diagram of a power supply circuit of the semiconductor storage device according to Embodiment 1 of the present invention.

FIG. 8 is an example of a circuit diagram of a signal voltage conversion circuit of the semiconductor storage device according to Embodiment 1 of the present invention.

FIG. 9 is an example of a configuration diagram of the signal voltage conversion circuit of the semiconductor storage device according to Embodiment 1 of the present invention.

FIG. 10 is an example illustrating a partial cross-sectional view of the memory array of the semiconductor storage device according to Embodiment 1 of the present invention.

FIG. 11 is an example illustrating a partial plane projection view of the memory array of the semiconductor storage device according to Embodiment 1 of the present invention.

FIG. 12 is an example illustrating a partial circuit configuration of a memory array of a semiconductor storage device according to Embodiment 2 of the present invention.

FIG. 13 is an example illustrating a partial operation of the memory array of the semiconductor storage device according to Embodiment 2 of the present invention.

FIG. 14 is an example illustrating a partial operation of a memory array of a semiconductor storage device according to Embodiment 3 of the present invention.

FIG. 15 is an example illustrating a partial circuit configuration of a memory array of a semiconductor storage device according to Embodiment 4 of the present invention.

FIG. 16 is an example illustrating a partial circuit configuration of the memory array of the semiconductor storage device according to Embodiment 4 of the present invention.

FIG. 17 is an example illustrating a partial operation of a memory array of a semiconductor storage device according to Embodiment 5 of the present invention.

FIG. 18 is an example illustrating a partial operation of the memory array of the semiconductor storage device according to Embodiment 5 of the present invention.

FIG. 19 is an example illustrating a partial operation of the memory array of the semiconductor storage device according to Embodiment 5 of the present invention.

FIG. 20 is an example of a configuration diagram of a power supply circuit of a semiconductor storage device according to Embodiment 6 of the present invention.

FIG. 21 is an example of a partial circuit configuration of a memory array of a semiconductor storage device according to Embodiment 7 of the present invention.

FIG. 22 is an example of a configuration diagram of a signal voltage conversion circuit of a semiconductor storage device according to Embodiment 8 of the present invention.

FIG. 23 is an example of a configuration diagram of a power supply circuit of a semiconductor storage device according to Embodiment 9 of the present invention.

### DESCRIPTION OF EMBODIMENTS

Hereinafter, embodiments will be described with reference to the drawings.

### Embodiment 1

An example of a semiconductor storage device 601 will be described in the present embodiment.

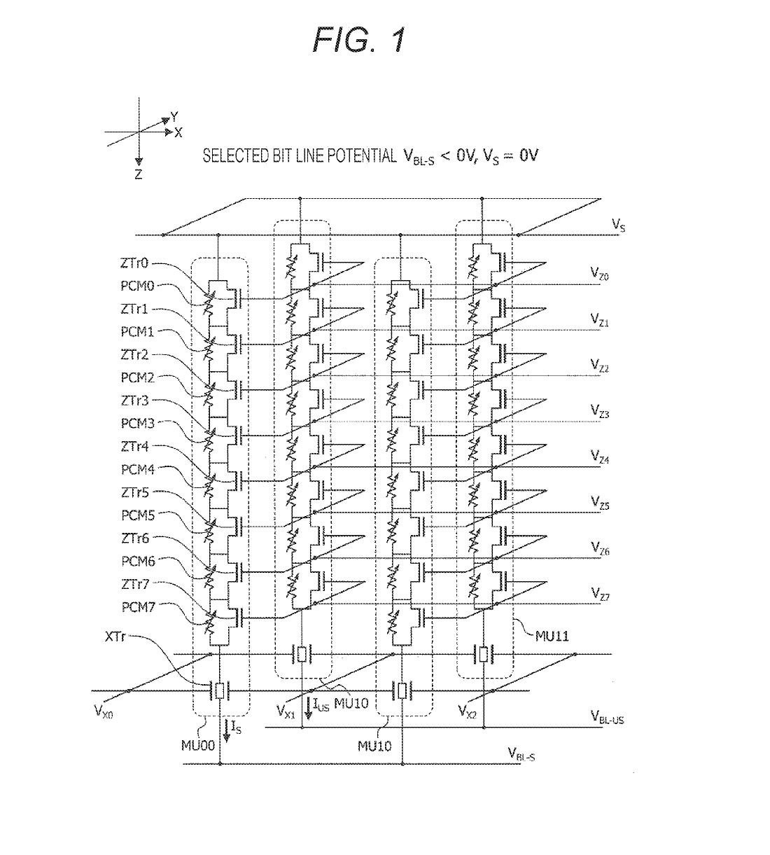

FIG. 1 is an example of a partial circuit configuration a memory array 602 of the semiconductor storage device 601 according to the present embodiment. The memory array 602 is configured of a plurality of memory chains MU. The memory chain is configured of a select element XTr, a plurality of phase change elements PCM, and a plurality of Z-select elements ZTr. The single phase change element PCM and the single Z-select element ZTr are connected in parallel, thereby forming a memory cell. A plurality of the memory cells are connected in series. Herein, the description is given with the example in which the single phase change element PCM and the single Z-select element ZTr are connected in parallel, but it is a matter of course that it is possible to provide a configuration in which the single phase change element PCM and the plurality of Z-select elements ZTr are connected in parallel, the plurality of phase change elements PCM and the single Z-select element ZTr are connected in parallel, or the plurality of phase change elements PCM and the plurality of Z-select elements ZTr are connected in parallel.

The Z direction is a direction perpendicular to the silicon substrate, and it is desirable that the X direction and the Y direction be perpendicular to the Z direction and perpendicular to each other. In this manner, it is possible to collectively form the memory cells, present in plural in the Z direction, with one-time drilling process, and to reduce the manufacturing cost.

Gate electrodes of the Z-select elements ZTr are connected layer by layer among the plurality of memory chains MU, and, for example, potentials of gate electrodes of zeroth layer Z-select transistors ZTr0 are set to the same potential, VZ0 in all the memory chains MU. When such a configuration is provided, there is an effect that a chip area of the semiconductor storage device 601 is reduced by reducing a wiring area of the gate electrode of the Z-select transistor, and it is possible to provide the cheap semiconductor storage device 601. Incidentally, it is a matter of course that it is possible to separate the gate electrodes of the Z-select transistors for each bit line, and to control the potentials thereof individually. In addition, it is a matter of course that it is possible to separate the gate electrodes of the Z-select transistors for each X-select line, and to control the potentials thereof individually. In this case, it is possible to control the gate potential of the Z-select transistor ZTr optimally for each location, and thus, a gate breakdown voltage of the Z-select transistor ZTr is set to be low, and there is an effect of improving the reliability of the semiconductor storage device 601.

It is desirable that a vertical GAA-NMOSFET (Gate All Around n-channel MOSFET) be used as the Z-select element ZTr. When the NMOSFET having a higher current driving force than a PMOSFET is used, it is possible to increase the number of the phase change elements PCM included in the memory chain MU, and to realize the semiconductor storage device 601 having the large capacity. Of course, it is a matter of course that the PMOS can be used. It is possible to reduce a size of the transistor to 4F2 (F is the minimum processing dimension), which is smaller than the case of using the planar MOS, by using the vertical MOSFET, and thus, it is possible to increase the capacity. When the GAA structure is provided, it is possible to widen a gate width as compared to the case of using the planar MOS, and accordingly, it is possible to improve a driving force of the MOS, to increase the number of the memory cells included in the phase change chain MU, and to increase the capacity. A voltage to be applied to a gate electrode of an unselected Z-select transistor can be decreased by using the PMOS as compared to the case of using the NMOS, and thus, the gate breakdown voltage of the Z-select MOS is set to be low, and there is the effect of improving the reliability of the semiconductor storage device 601.

It is possible to use a chalcogenide material, and particularly, a GeSbTe alloy (germanium-antimony-tellurium alloy) as a part of a material of the phase change element PCM. The chalcogenide material can be set to have both metastable states of an amorphous (non-crystalline) state and a crystalline state, and electrical resistance values of the respective states are different from each other. That is, a high resistance is obtained in the amorphous state, and a low resistance is obtained in the crystalline state. It is possible to store values of “0” and “1” using such a difference in electrical resistance. The amorphous state is set as “0”, and the crystalline state is set as “1”. An operation of rewriting “0” to “1” is set as erase, and an operation of rewriting “1” to “0” is set as write. The rewrite is performed by causing the current to flow in the phase change element PCM to generate the Joule heat. The phase change element is crystallized by being held at a crystallization temperature or higher for a certain period of time in order to perform the erase. The phase change element is heated to a melting point or higher and is rapidly cooled, thereby being amorphized (vitrified) in order to perform the write. It is a matter of course that it is possible to use three values or more of the phase change element PCM. When the phase change element that has been already applied to a product is used as a storage element, there are effects that it is possible to shorten a development period, and to ship the semiconductor storage device 601 in a short period of time. Incidentally, the present embodiment has been described with the example in which the phase change of crystal-amorphous is performed as the phase change element, but it is a matter of course that it is possible to use one that performs a phase change of crystal A-crystal B. Here, the crystal A and the crystal B are crystals having different crystal structures.

Incidentally, the present embodiment has been described with the example in which the phase change element is used as the storage element, but it is a matter of course that it is possible to use a ReRAM or a STT-MRAM (spin-injection MRAM) as the storage element. It is possible to increase the number of storage elements included in the single memory chain MU by using the ReRAM with a low rewrite current, and there is an effect of realizing the semiconductor storage device 601 having the large capacity. In addition, when the STT-MRAM with a high rewrite speed is used, there is an effect that the semiconductor storage device 601 with a high write data rate can be realized. Hereinafter, a description will be given regarding a case in which the phase change element is used as the storage element.

The write and the erase are performed by causing a write current to flow in the phase change element PCM to generate the Joule heat. The write current is, for example, 40 μA, and an erase current is, for example, 20 μA. Incidentally, it is also logically possible to perform the write or the erase by causing a current to flow between neighboring Z-select MOS to generate the Joule heat.

The read is performed by applying a read voltage to the phase change element PCM, then amplifying a change in voltage of a bit line caused by the current that has passed through the phase change element PCM and flows in a source electrode using a sense amplifier, and determining “0” and “1”.

It is desirable to use a double-gate NMOSFET as the X-select element XTr. It is possible to obtain a wider gate width of the MOSFET by using the double-gate MOSFET as compared to the case of using the planar MOSFET, and thus, it is easy to secure the current required for the write of the phase change element PCM. Thus, there is an advantage that it is possible to improve the yield of the semiconductor storage device 601. In addition, it is possible to increase the number of memory cells included in the memory chain since the driving force of the MOSFET is improved. Further, it is possible to set the cell area of the memory chain MU to 4F2 (F is the minimum processing dimension), which is smaller than 6 to 8F2 of the case of using the planar MOSFET, and thus, it is possible to realize the semiconductor storage device 601 having the large capacity. The double-gate NMOSFET has two gate electrodes, and the MOS is turned on (into a low-resistance state) when ON-voltage is applied to both the gate electrodes. The MOS is turned off (into a high-resistance state) when the ON-voltage is applied only to one of the gate electrodes, or when OFF-voltage is applied to all the gate electrodes. Hereinafter, a description will be given assuming a case of using the double-gate NMOSFET.

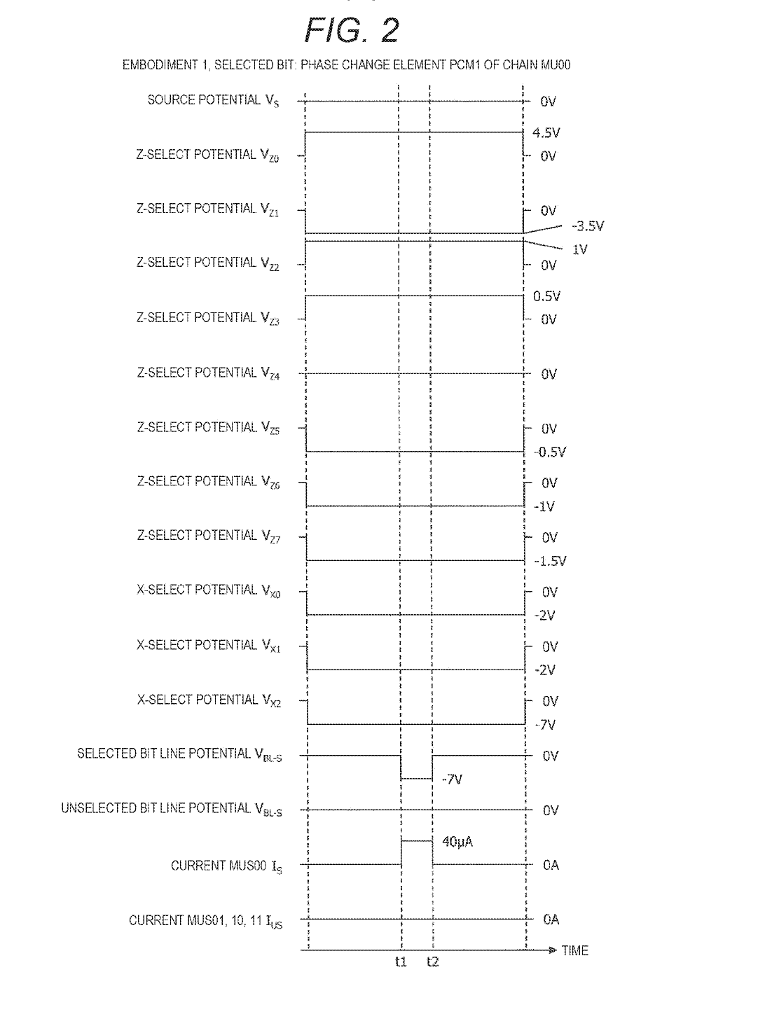

Characteristics of the present invention will be described with reference to FIG. 2 which illustrates the write operation.

The description will be given with an example in which a selected chain is indicated by MU00, and the write is performed in a phase change element PCM1.

A negative voltage, for example, −7 V is applied to a selected bit line at the time of write. The voltage is defined such that a ground potential is 0 V. A ground potential VSS can be supplied from the outside of the semiconductor storage device 601. Incidentally, a power-supply voltage VDD is also supplied from the outside of the semiconductor storage device 601. To be specific, it is a matter of course that a potential of a selected bit line VBL-S becomes slightly higher than a potential of a write driver when compared with the potential of the write driver that drives the selected bit line VBL-S due to a voltage drop in a wiring from the write driver to the selected bit line VBL-S and an access transistor. A voltage of the write driver is, for example, −7.5 V.

When a description is given assuming that a voltage between the drain and the source of the MOS in the on-state is 0.5 V, and a voltage between the gate and the source thereof is 5 V, and a voltage between the gate and the source of the MOS in the off-state is 0 V, each of two gate voltages of the X-select transistor may be set to −2 V in order to set a source voltage of −7 V, and the voltage between the gate and the source of 5 V when focusing on the X-select transistor XTr of the selected chain MU00. A drain voltage of the X-select transistor XTr becomes −6.5 V as the voltage between the drain and the source of the MOS in the on-state is 0.5 V, and the source voltage is −7 V.

In addition, at least one gate voltage of the X-select transistor may be set to −7 V in order to unselect the X-select transistor. An X-select potential VX2 is controlled to be −7 V in the case of FIG. 2.

When focusing on a Z-select transistor ZTr7 of the selected chain MU00, a source voltage is the same as the drain voltage of the X-select transistor XTr, that is, −6.5. Thus, a gate voltage of the Z-select transistor ZTr7 of the selected chain MU00 may be set to −1.5 V in order to set the source voltage of −6.5 V and a voltage between the gate and the source of 5 V.

Hereinafter, gate voltages of Z-select transistors ZTr6, ZTr5, ZTr4, ZTr3 and ZTr2 may be set to −1 V, −0.5 V, 0 V, 0.5 V and 1 V, respectively, in the same manner.

A Z-select transistor ZTr1 is turned off to cause the current to flow not into the transistor but into the phase change element in order to select the phase change element PCM1. A source voltage of the Z-select transistor ZTr1 is −3.5 V, and thus, a gate voltage may be set to −3.5 V in order to turn off the Z-select transistor ZTr1. At this time, a write voltage of 3 V is applied to the phase change element PCM1, and thus, a drain voltage of the Z-select transistor ZTr1 becomes −0.5 V. A source voltage of the Z-select transistor ZTr0 is −0.5 V, and thus, each gate voltage may be set to 4.5 V.

A write current, for example, 40 μA is caused to flow into the selected chain MU00 over time t1 to t2 at the time of write. Meanwhile, the current does not flow into unselected chains MU01, MU10 and MU11.

A potential VS of the source electrode becomes substantially 0 V. Incidentally, strictly speaking, it is a matter of course that the potential of the source electrode is slightly higher than 0 V, which is the potential of a GND terminal due to a voltage drop in the current flowing from the source electrode to the GND terminal.

Here, it is understood that the voltage between the gate and the source is 5 V or lower in all the Z-select transistors ZTr including the selected chain and the unselected chain. That is, it is understood that the fact, which has been described in as the above-described problem, that the voltage between the gate and the source of the Z-select transistor ZTr becomes high, for example, 11 V is solved by using the negative voltage as the voltage to be applied to the selected bit line.

Here, a reason that causes the voltage drop between the source and the drain of the unselected Z-select MOS and in the selected phase change element PCM will be reviewed. The phase change element, the ReRAM and the STTMRAM are current rewrite-type non-volatile memory element having two terminals, and the rewrite is performed by causing the current to flow from one terminal of the memory elements to the other terminal. At this time, a certain write current I is required for the rewrite. In addition, the memory element has a certain dynamic resistance R. The dynamic resistance is a resistance of the memory element during the rewrite. At this time, it is possible to obtain a voltage drop amount V from the following Formula (1) of the Ohm's law.

V=RI (1)

This voltage drop amount V is enough large not to be ignored with respect to the write voltage, for example, 7.5 V, and thus, it is necessary to consider the voltage drop in the memory element regarding the operation of the semiconductor storage device 601. Incidentally, strictly speaking, a little off-current flows also in the Z-select transistor, and thus, the exact voltage drop amount is slightly different from one obtained from Formula (1).

Further, the memory cells are connected in series, and most of current is caused to flow via the Z-select transistor in the unselected memory cell inside the selected memory chain. It is possible to obtain the voltage drop amount in the unselected memory cell from a product of the resistance between the source and the drain of the Z-select transistor and the write current. Incidentally, strictly speaking, it is a matter of course that a little current also flows in the phase change element of the unselected memory cell.

Here, it is possible to set a write current I to be extremely low in the case of using so-called NAND flash memory or FeRAM (ferroelectric memory) of a floating gate type or a charge trap type of a voltage rewrite system as the non-volatile memory, and thus, the problem caused by the voltage drop hardly occurs.

Further, since a potential of the source potential VS is constantly kept to 0 V, it is possible to provide an array configuration having a large parasitic capacitance of a source line, to increase the number of the memory chains MU connected to the source line, and to reduce the area of the memory array 602, and thus, it is possible to realize the semiconductor storage device 601 with the low manufacturing cost. Further, when the voltage of the source line varies in a structure in which the select transistor is not provided between the memory cell and the source line, a voltage of the memory cell also varies, and thus, a disturb current flows into the phase change element PCM. This adversely affects the operation reliability. Such a problem does not occur in the present system in which the potential of the source line is kept to be constant.

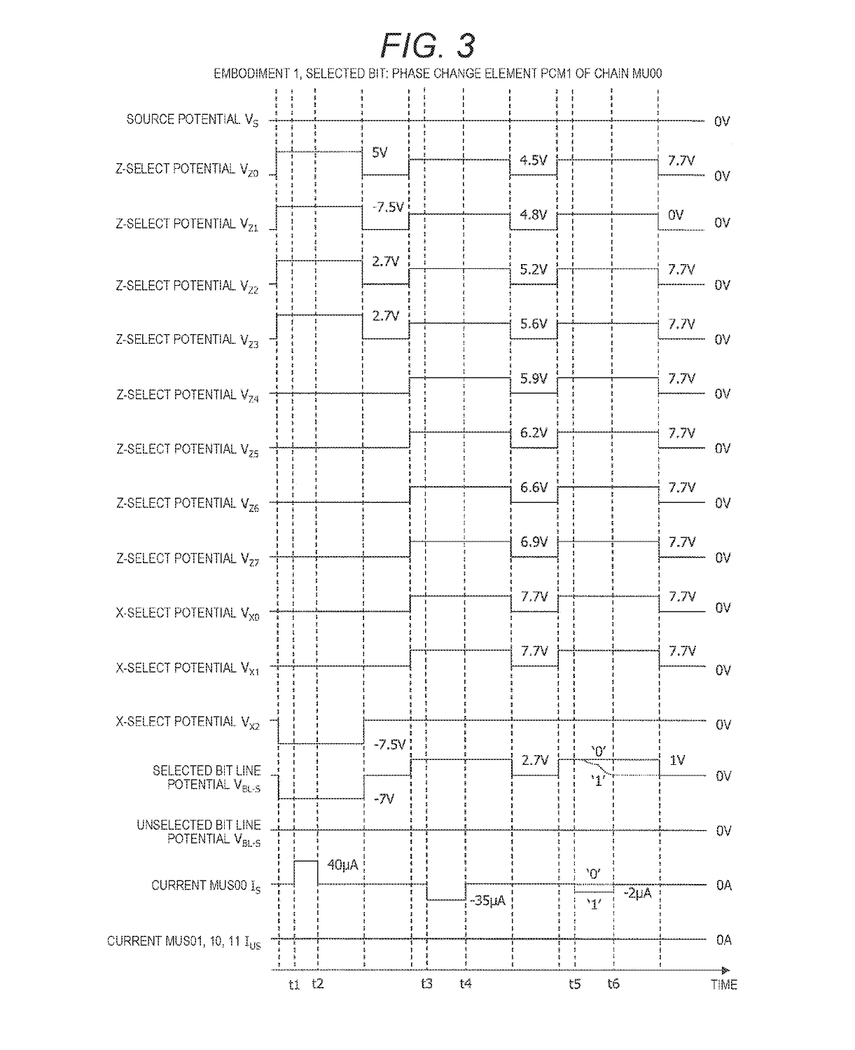

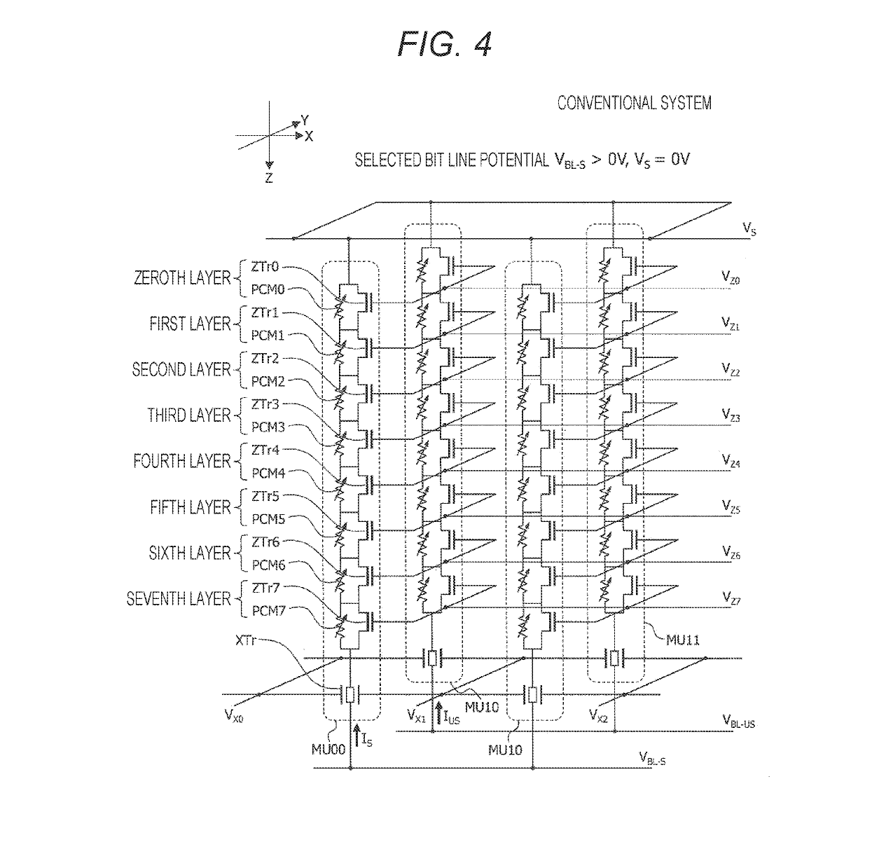

Another operation using the present invention will be described with reference to FIG. 3.

FIG. 3 illustrates a configuration in which a voltage level to be used is reduced. Through such a reduction, it is possible to reduce the area of a power supply circuit, and to realize the semiconductor storage device 601 with the low manufacturing cost. FIG. 3 illustrates a case in which the selected memory chain is indicated by MU00, and the selected bit is the phase change element PCM1 thereof.

A breakdown voltage between the gate and the source of the Z-select MOS is set to be a breakdown voltage, for example, 7.7 V, which is higher than 5 V, for example in the example of FIG. 2. A write current, for example, 40 μA flows over the time t2 to t3. At this time, a Z-select potential VZ7 is set to 0 V. In FIG. 2, the Z-select potential VZ7 is −1.5 V, and the voltage between the gate and the source is 5 V. In FIG. 3, the Z-select potential VZ7 is 0 V, and the voltage between the gate and the source becomes, for example, 6.5 V. This voltage is lower than the breakdown voltage of 7.7 V, which does not hinder the reliability of the MOS. In this manner, it is unnecessary to prepare the voltage of −1.5 V, and it is possible to reduce the voltage level.

Next, the erase operation will be described with reference to FIG. 3.

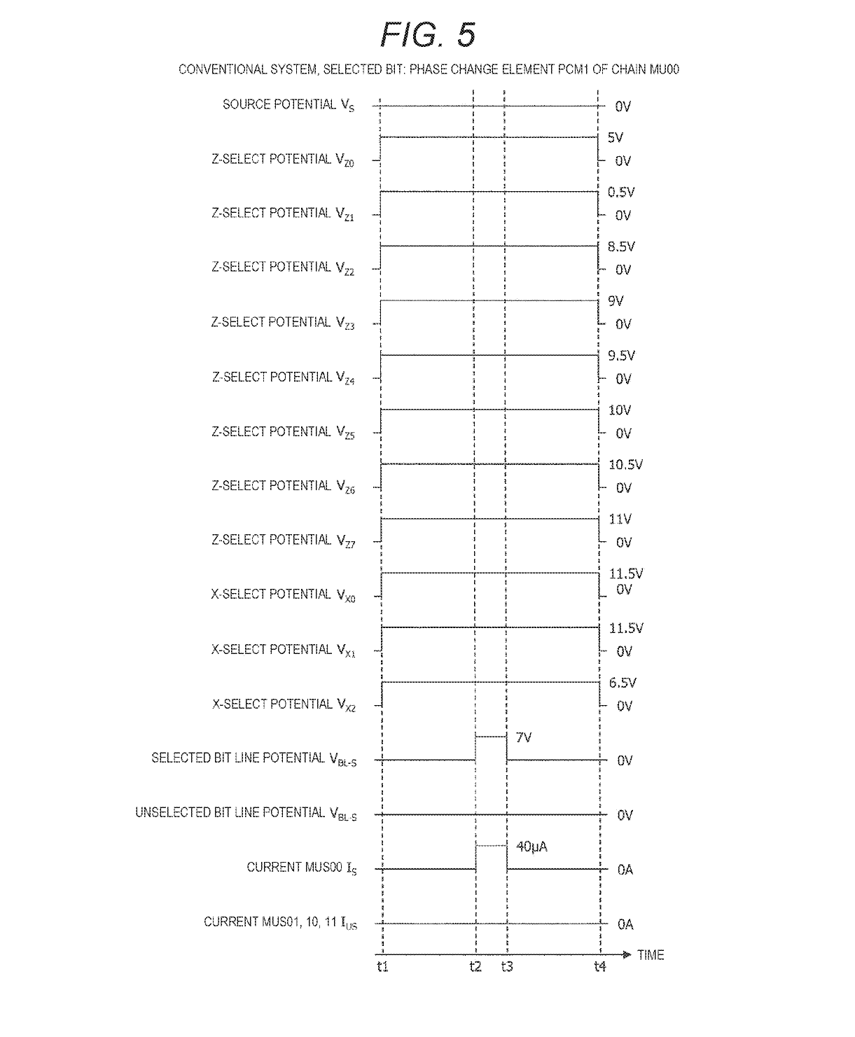

A current at the time of erase is, for example, 35 μA. It is desirable that temperature of the phase change element heated by the Joule heat at this time be lower than temperature of the phase change element at the time of write. The current is caused to flow between the source and the drain of the Z-select transistor ZTr, thereby generating the Joule heat (bundle erase) in this example. That is, the Joule heat is generated in a channel of the Z-select transistor, and this heat is transferred to the phase change element PCM, thereby crystallizing the phase change element PCM. The voltage between the gate and the source of the Z-select transistor ZTr is set to 4.5 V. It is desirable that the Z-select transistor ZTr not be completely turned on. Accordingly, it is possible to increase the Joule heat which is generated in the Z-select transistor ZTr with respect to the same current between the source and the drain. The amount of the generated Joule heat is equalized in each of the memory cells, and thus, it is desirable to finely control the potential of the Z-select for each layer, and to control the gate voltage of the Z-select transistor using at least five or more levels of potentials as compared to the write. Since the gate voltage is low as compared to the case of FIG. 5, it is possible to perform the control of the gate voltage with five or more levels while saving power, and to realize the power-saving semiconductor storage device 601.

It is possible to collectively erase the phase change elements of the plurality of memory cells through the bundle erase. It is desirable to erase all the memory chains at the same time. It is because it is likely to erase a memory cell adjacent to an erase region by mistake when erasing only some of the memory chains. Further, it is desirable to collectively erase the plurality of memory chains. Accordingly, it is possible to heat an adjacent memory chain or reduce the escape of heat using heat generated from a single memory chain, to reduce electrical energy required for the erase, and to realize the semiconductor storage device 601 which is capable of the high-speed erase. Incidentally, a reason that enables the reduction of the escape of heat is because a difference in temperature between memory chains is decreased when a memory chain adjacent to a certain memory chain is heated, and a heat flux between the memory chains is reduced from the Fourier's law that a heat flux density is proportional to a difference in temperature.

Here, it is desirable that a potential of the selected bit line VBL-S be a positive voltage at the time of erase. For example, the potential is 2.7 V. This is because it is possible to supply the voltage to be applied to the selected bit line VBL-S at the time of erase without using a booster circuit by supplying the power-supply voltage VDD of for example, 2.7 to 3.6 V, and using 2.7 V, which is the minimum voltage of the power-supply voltage VDD for the erase, and it is possible to increase the number of memory chains that can be erased at the same time to, for example, 512 by eliminating the power loss in the booster circuit. Accordingly, it is possible to improve an erase speed to, for example, 400 MB/s.

It is desirable that a potential of the selected bit line VBL-S be a positive voltage at the time of read. For example, the potential is 1 V. It is possible to perform the power supply without using the booster circuit by using the positive voltage, and to reduce power consumption of the read. Accordingly, it is possible to provide the semiconductor storage device 601 with the low power consumption.

In addition, the bit line potential is low such as 2.7 V or 1.0 Vat the time of erase or read, and thus, it is possible to realize the high-speed semiconductor storage device 601.

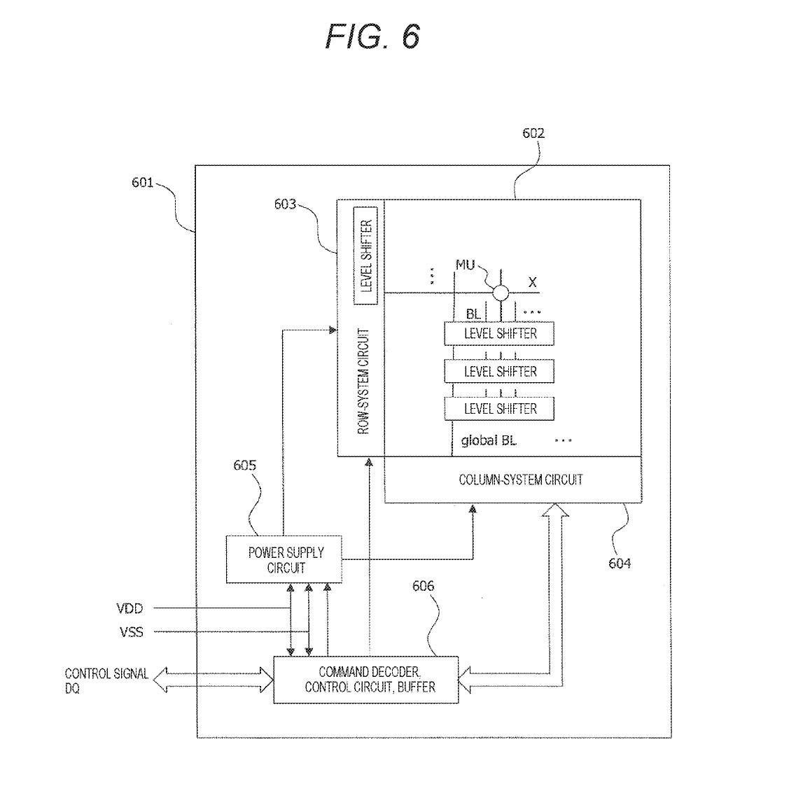

FIG. 6 illustrates a configuration of the semiconductor storage device 601.

The power-supply voltage VDD and the ground voltage VSS are supplied to the semiconductor storage device 601 from the outside of the chip, and communication thereof is performed using a control signal and a data signal line DQ. Examples of an input control signal include a chip effective signal CE, a command latch effective signal CLE, an address latch effective signal ALE, a clock signal CLK, a read/write effective signal W/R#, and a write protect signal WP#, an example of an input/output control signal is a data strobe DQS, and an example of the output control signal is a read/busy signal R/B#. In addition, it is possible to supply an I/O signal power supply VCCQ and an I/O signal ground source VSSQ.

The semiconductor storage device 601 is provided with a command decoder, a control circuit, a buffer device 606, a power supply circuit 605, a column-system circuit 604, a row-system circuit 603, and the memory array 602. The power supply circuit supplies power to the column-system circuit 604, the row-system circuit 603, the command decoder, the control circuit, and the buffer device 606. Some voltages thereof are stepped up or down, and the other voltages are directly supplied as the power-supply voltage VDD.

It is desirable that a voltage of a control signal supplied from the command decoder, the control circuit, and the buffer device 606 to the row-system circuit be 2.3 V. An X-select potential VX is a positive voltage as compared to −7 V, for example, in the example of FIG. 2, and, it is possible to reduce the power consumption of the semiconductor storage device 601 by using a signal having a low absolute value of the voltage. The row-system circuit is provided with a signal voltage conversion circuit, that is, a level shifter, and performs conversion of a signal voltage level from 2.3 V to −7 V using the level shifter.

Next, it is desirable that a voltage of a control signal supplied from the command decoder, the control circuit, and the buffer device 606 to the column-system circuit be 2.3 V. A potential of the selected bit line VBL is a positive voltage as compared to −7 V, for example, in the example of FIG. 2, and, it is possible to reduce the power consumption of the semiconductor storage device 601 by using a signal having a low absolute value of the voltage. The column-system circuit is not provided with the signal voltage conversion circuit, that is, the level shifter, and it is desirable to arrange a plurality of level shifters in the memory array 602 to perform the conversion of the signal voltage level from 2.3 V to −7 V. A column-system signal has a signal pulse width of, for example, 10 ns, which is shorter than a pulse width of a row-system signal, for example, 2 μs, and thus, the influence that switching of this signal affects the power consumption of the semiconductor storage device 601 is great as compared to that in the row-system circuit. Thus, when the column-system circuit is driven with, for example, 2.3 V, a global bit line global BL is driven with 2.3 V, and the conversion of signal voltage is performed using the level shifter in the vicinity of a region to be driven among the plurality of level shifters in the memory array 602, it is possible to realize the semiconductor storage device 601 having the low power consumption. The level shifters drive a plurality of bit lines BL. That is, it is desirable that the number of the level shifters be larger than the total number of the row-system circuit and the column-system circuit.

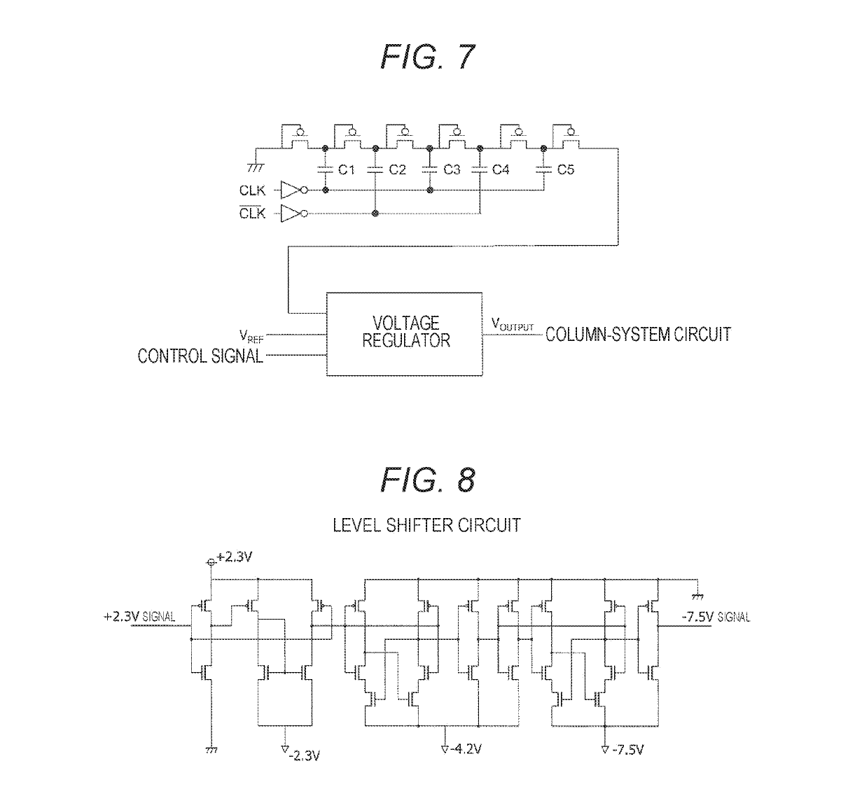

Next, the power supply circuit will be described with reference to FIG. 7.

The power supply circuit is configured of the booster circuit and a voltage regulator. It is desirable to use a Dickson booster circuit illustrated in FIG. 7 as the booster circuit. It is possible to design the power supply circuit for a short period of time by using the mostly proven Dickson booster circuit. The voltage regulator generates an output voltage Voutput based on a reference voltage Vref and the control signal. This voltage is supplied to the column-system circuit. The output voltage Voutput is, for example, −7.5 V. When this voltage is affected by the voltage drop in the wiring from the write driver to the selected bit line VBL-S and in the access transistor, the potential of the selected bit line VBL-S becomes −7 V.

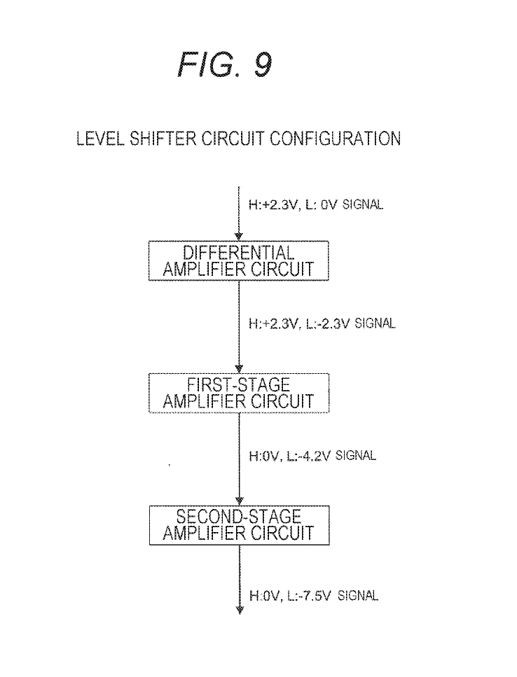

Further, the level shifter circuit will be described with reference to FIGS. 8 and 9.

As illustrated in FIG. 9, the level shifter circuit is configured using a differential amplifier circuit, a first-stage amplifier circuit, and a second-stage amplifier circuit. A signal having a high-voltage side H of 2.3 V and a low-voltage side L of 0 V is converted into a signal having a high-voltage side H of 2.3 V and a low-voltage side L of −2.3 V using the differential amplifier circuit, and thereafter, is converted into a signal having a high-voltage side H of 0 V and a low-voltage side L of −4.2 V and a signal having a high-voltage side H of 0 V and a low-voltage side L of −7.5 V using the voltage amplifier circuits. The power loss at the time of voltage conversion is reduced by forming the two-stage voltage amplifier circuit.

A detailed circuit configuration is illustrated in FIG. 8. It is possible to form the circuit using the PMOSFET and the NMOSFET.

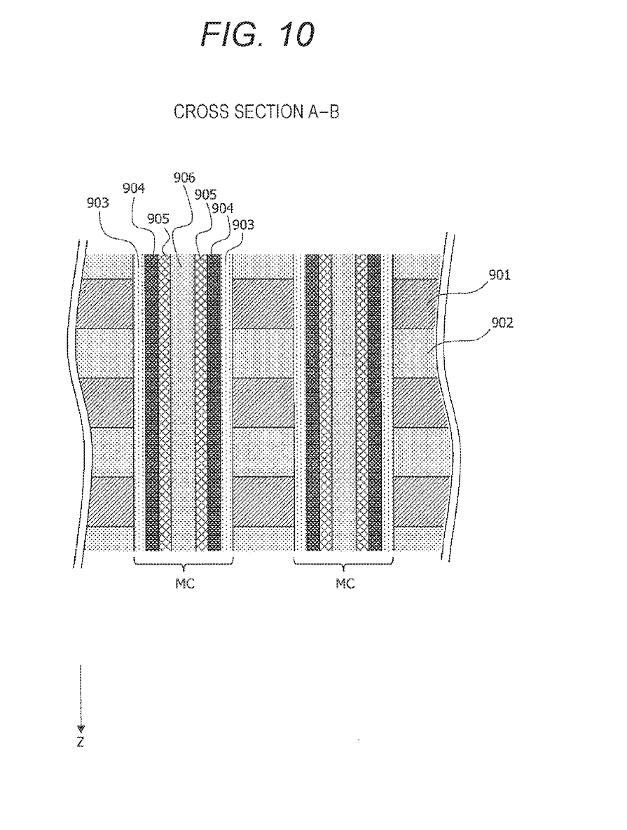

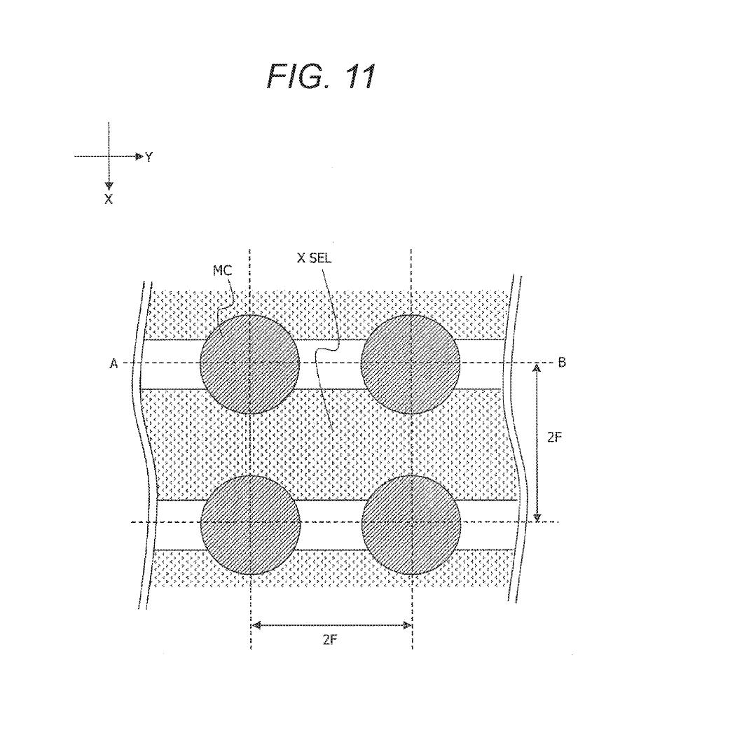

A partial structure of the plurality of memory chains MC will be described with reference to FIGS. 10 and 11. The four memory chains MC are arranged in FIG. 11. A pitch (period) of the memory chains is 2F in both the X direction and the Y direction. The memory chain MC is arranged in a clearance in an X-select line X SEL.

FIG. 10 illustrates a cross section A-B of FIG. 11. A silicon oxide film 906, a gate oxide film 903, a silicon channel 904, a phase change material 905, a Z-select transistor gate electrode 901, an interlayer insulating film 902, and the memory chain MC are illustrated.

### Embodiment 2

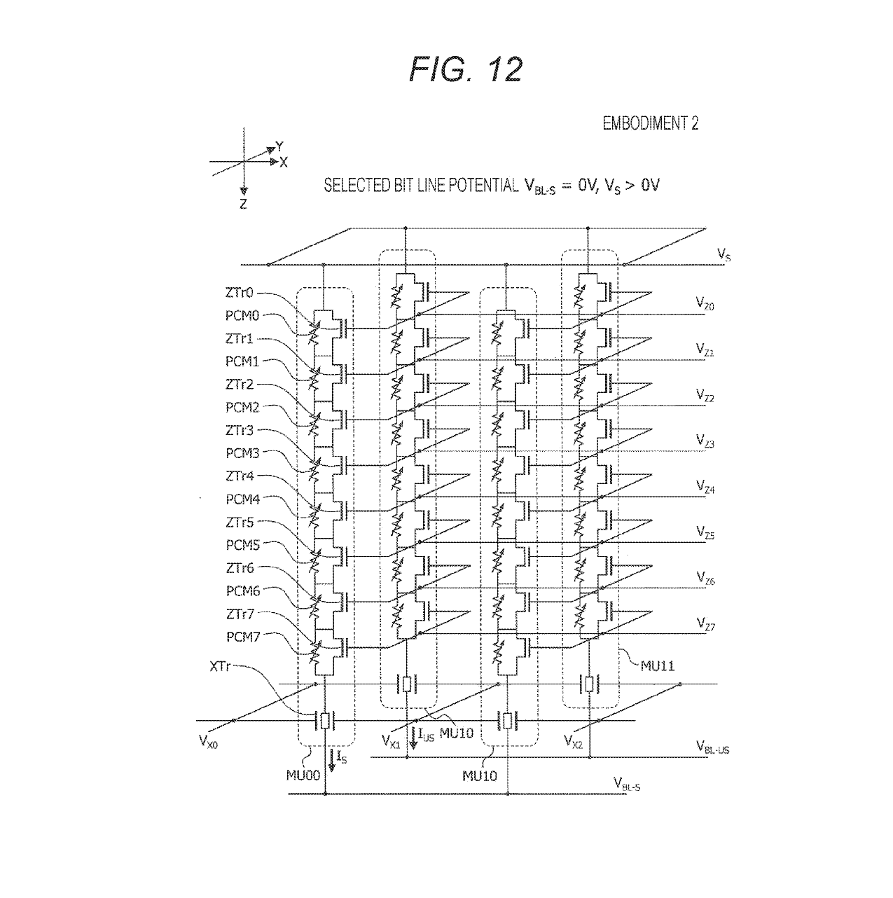

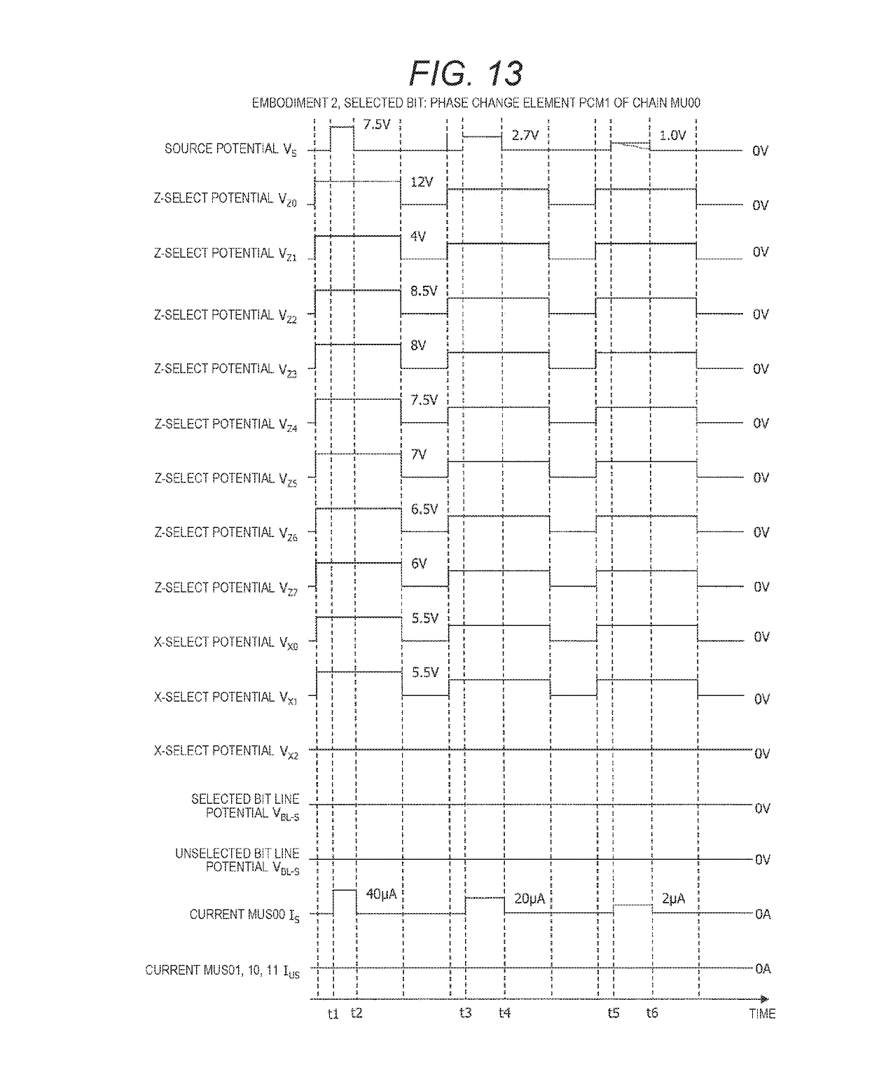

A description will be given regarding an example of a semiconductor storage device which is capable of high-speed write with reference to FIGS. 12 and 13 in the present embodiment.

FIG. 12 is an example of a configuration diagram illustrating the semiconductor storage device 601 according to Embodiment 2.

A description will not be repeated regarding the configurations attached with the same reference numerals and parts having the same functions as illustrated in FIG. 1 which has been already described.

In FIG. 13, a potential of the selected bit line VBL-S is 0 V, and a source potential VS is 7.5 Vat the time of write. In this manner, the source potential of the Z-select transistor of the unselected memory chain increases, and thus, there is the effect that the breakdown voltage between the gate and the source of the unselected memory chain is set to be low.

To be specific, a memory cell is connected to a source line without a select element interposed therebetween. Thus, the source electrodes of all the Z-select transistors of the unselected chain MU are electrically connected to a source destination via the phase change element PCM. Thus, the source voltages of all the Z-select transistors of the unselected chain MU become 7.5 V. On the other hand, the Z-select potential VZ is between 12 V and 4 V, and thus, each voltage between each gate and each source of all the Z-select transistors of the unselected chain MU becomes −3.5 to 4.5 V. That is, the voltage becomes lower than 11 V illustrated in FIG. 5.

A negative voltage is not used in the present embodiment, and thus, it is possible to decrease the area of the power supply circuit, and to provide the semiconductor storage device with the low cost. In addition, the source potential is low such as 2.7 V and 1.0 V at the time of erase or read, and thus, it is possible to realize the high-speed semiconductor storage device 601.

### Embodiment 3

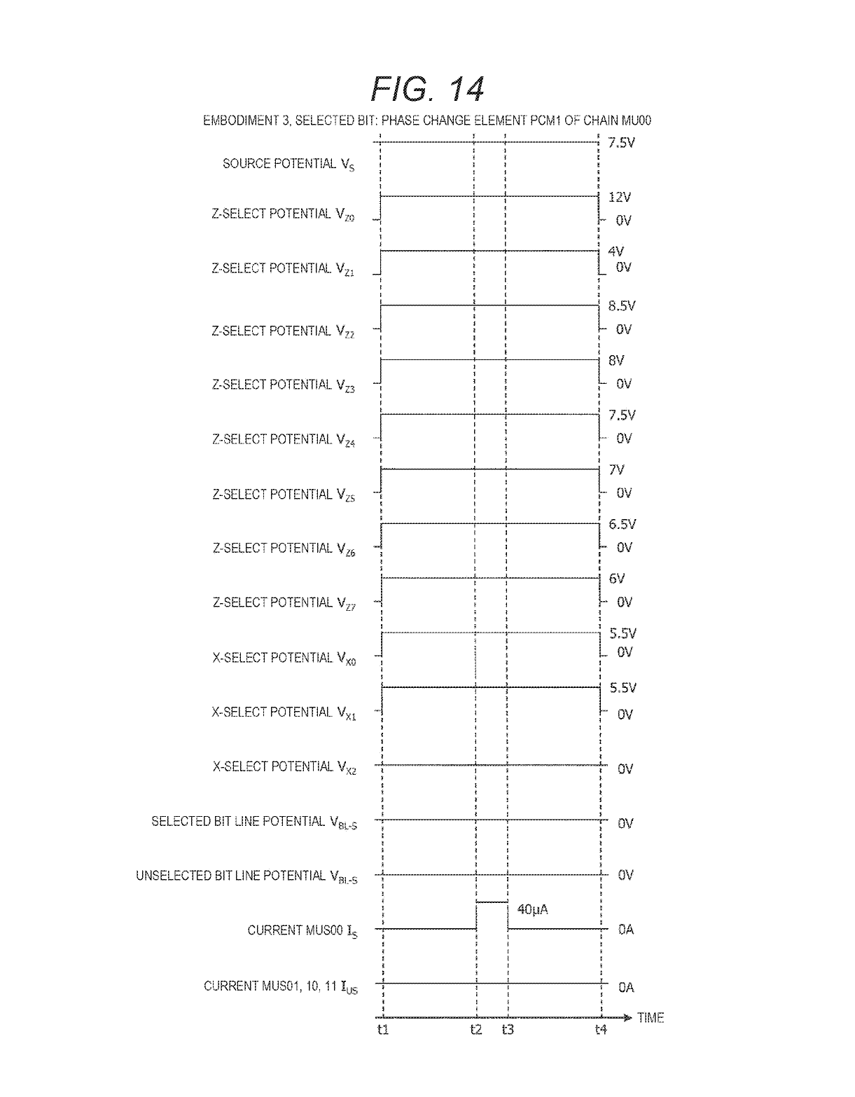

A description will be given regarding an example of a semiconductor storage device with a small chip area and low manufacturing cost with reference to FIG. 14 in the present embodiment.

FIG. 14 is an operation example of the semiconductor storage device 601 according to Embodiment 3. A description will not be repeated regarding the configurations attached with the same reference numerals and parts having the same functions as illustrated in FIG. 2 which has been already described.

In FIG. 14, a potential of the selected bit line VBL-S is 0 V, and the source potential VS is 7.5 Vat the time of write. In this manner, the source potential of the Z-select transistor of the unselected memory chain increases, and thus, there is the effect that the breakdown voltage between the gate and the source of the unselected memory chain is set to be low.

Further, the source potential VS is kept to be 7.5 V also at the time of read and erase. Thus, the disturb current does not flow in the phase change element PCM in the memory chain MU. Further, since the source potential is kept to be constant, there is no need of reducing the parasitic capacitance of the source line.

A difference in potential between the selected bit line and the source line is set to 2.7 V by applying a voltage of, for example, 4.8 V to the selected bit line at the time of erase.

A difference in potential between the selected bit line and the source line is set to 1 V by applying a voltage of, for example, 6.5 V to the selected bit line at the time of read. Further, the following configuration is essential in order to reduce the gate breakdown voltage by keeping the voltage of the source line to be 7.5 V. That is, the number of memory chains connected to the same source line needs to be larger than the number of gate electrodes of the Z-select transistors, which are connected to one electrode and controlled to be the same potential. When such a configuration is provided, the area of the memory array 602 is reduced with a minimum control circuit, and a problem that a source voltage is caused to decrease, and a high voltage is applied between the gate and the source of the unselected Z-select transistor when a high voltage at the time of write is applied to the gate electrode of the Z-select transistor does not occur.

To put it another way, it is necessary to control the source voltage such that the voltage applied to the gate is constantly a certain voltage or lower, for example, 5 V or lower in order to solve the problem of the gate breakdown voltage. Since it is desirable that the memory array 602 include the plurality of Z-select lines and the plurality of source lines, it is necessary to control potentials of the source line and the Z-select line while constantly considering the gate breakdown voltage.

In other words, it is necessary to apply a voltage of at least 6 V or higher to the source line of a region when a high voltage of, for example, 11 V is applied to the Z-select line even in the region that does not include a memory chain as a write target in the example in which the gate breakdown voltage is 5 V.

Incidentally, when 7.5 V is precharged to all the source lines of the chip, a problem that the amount of consumed power increases occurs. Thus, it is desirable to supply 7.5 V to the source line only in a minimum required region.

### Embodiment 4

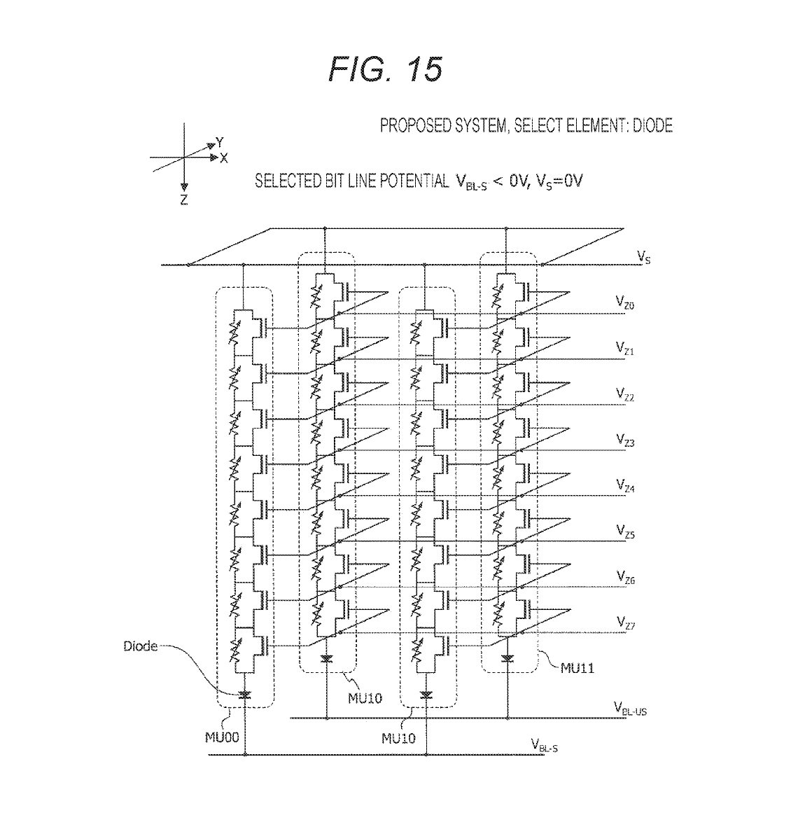

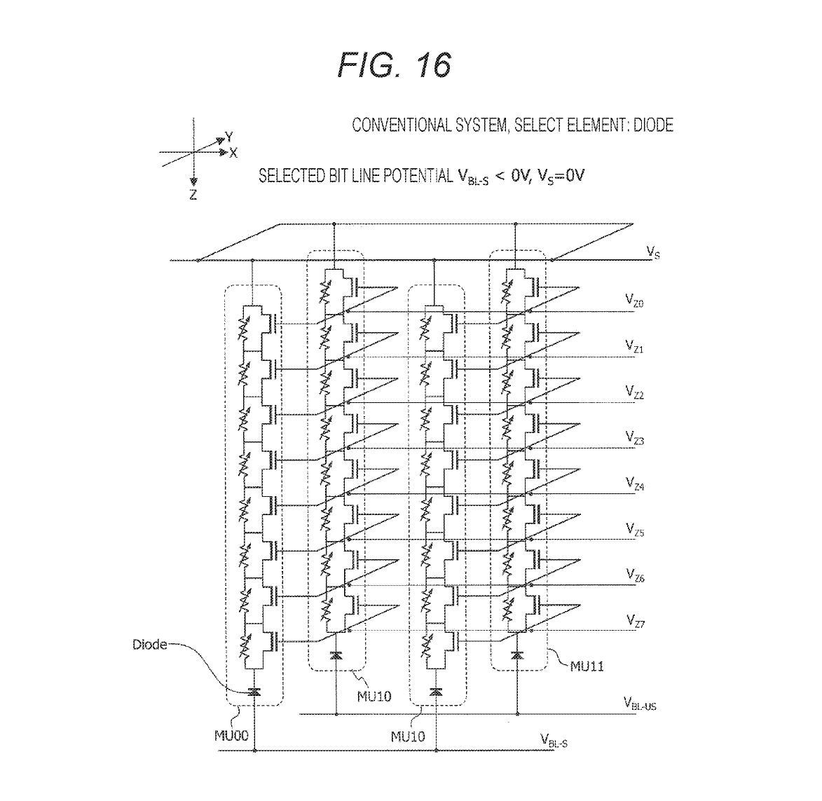

A description will be given regarding an example of a semiconductor storage device with a small number of process steps and low manufacturing cost with reference to FIG. 15 in the present embodiment. In addition, FIG. 16 will be used for comparison.

The potential of the selected bit line VBL-S is higher than the potential VS of the source line, and the current flows from the selected bit line toward the source line in FIG. 16 that is used for comparison. The potential VS of the source line is 0 V. In this case, some of the gate voltages of the Z-select transistors become high such as 11 V, which is similar to FIG. 5, and the source voltage of the Z-select transistor of the unselected chain is 0 V, and thus, there occurs a problem that the voltage between the gate and the source becomes higher.

On the other hand, a negative voltage, for example, −7 V is used as the voltage of the selected bit line as illustrated in FIG. 15 in the present embodiment. In this case, the current flows from the source line to the selected bit line. A polarity of a diode is different between FIGS. 15 and 16. In this manner, it is possible to reduce the voltage between the gate and the source to be, for example, 5 V or lower, and to realize the highly reliable semiconductor storage device 601 which is similar to Embodiment 1.

Further, it is possible to realize the semiconductor storage device with the low manufacturing cost by using the diode, which can be manufactured with the smaller number of steps as compared to the double-gate MOSFET according to Embodiment 1, as the select element.

### Embodiment 5

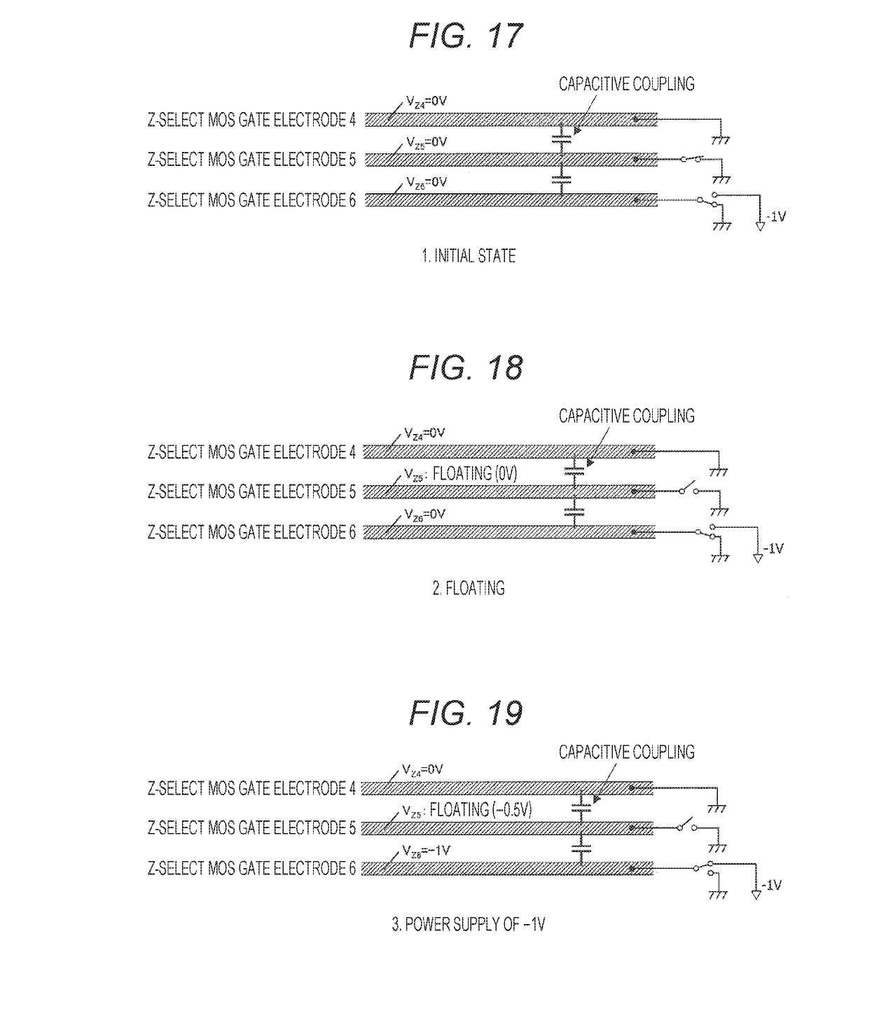

A description will be given regarding an example of a semiconductor storage device with a small chip area and low manufacturing cost with reference to FIGS. 17 to 19 in the present embodiment. A description will not be repeated regarding the configurations attached with the same reference numerals and parts having the same functions as illustrated in FIG. 1 which has been already described.

FIG. 17 illustrates Z-select MOS gate electrodes 4, 5 and 6 which are parts of the memory array 602. A voltage of 0 V is applied to each of the electrodes.

The respective Z-select MOS gate electrodes can be regarded as a parallel plate capacitor, and are electrically coupled with each other through an electrical capacitance. Thus, when potentials of some of the electrodes are changed, potentials of other electrodes are changed in some cases. A voltage of the Z-select MOS gate electrode at the time of write is controlled using such a fact.

To be specific, the Z-select MOS gate electrode 5 is disconnected from a ground voltage to be a floating state as illustrated in FIG. 18.

Then, the connection of the Z-select MOS gate electrode 6 is switched from the ground voltage to a power supply of −1 V, thereby supplying −1 V to the Z-select MOS gate electrode 6 as illustrated in FIG. 19. At this time, the Z-select MOS gate electrode 5 is capacitively coupled between the Z-select MOS gate electrode 4 and the Z-select MOS gate electrode 6, and thus, a voltage of the Z-select MOS gate electrode 5 becomes −0.5 V which is a median potential thereof. That is, it is possible to control the voltage of the Z-select MOS gate electrode 5 to be −0.5 V without preparing a power supply of −0.5 V.

In this manner, when the number of power supply voltage levels is reduced and the area of the power supply circuit is reduced, it is possible to realize the semiconductor storage device with the small chip area and the low manufacturing cost.

### Embodiment 6

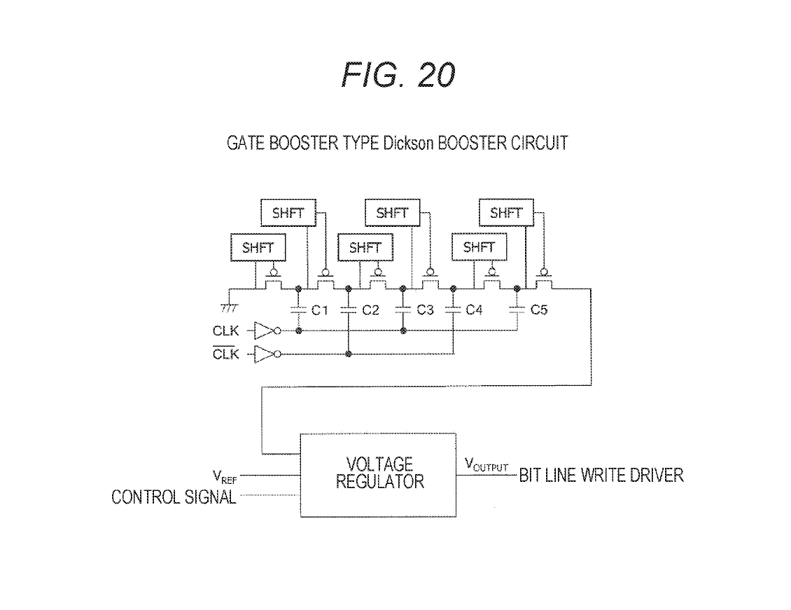

A description will be given regarding an example of a semiconductor storage device which is capable of high-speed rewrite with reference to FIG. 20 in the present embodiment.

FIG. 20 is a diagram illustrating a configuration of a power supply circuit. The Dickson booster circuit has a problem that a boostable voltage value decreases when a threshold voltage of the MOS is high.

Thus, the present embodiment provides a circuit configuration in which the boostable voltage value can be boosted to a high voltage without being affected by the threshold of the MOS by boosting a gate voltage of a transistor of the booster circuit using a booster circuit SHFT.

It is possible to increase the amount of current that can be used for the write by using such a booster circuit, and it is possible to realize write speed of 400 MB/s as the number of bits to be written in parallel increases, and the write is performed by the parallel operation of 32 bits.

### Embodiment 7

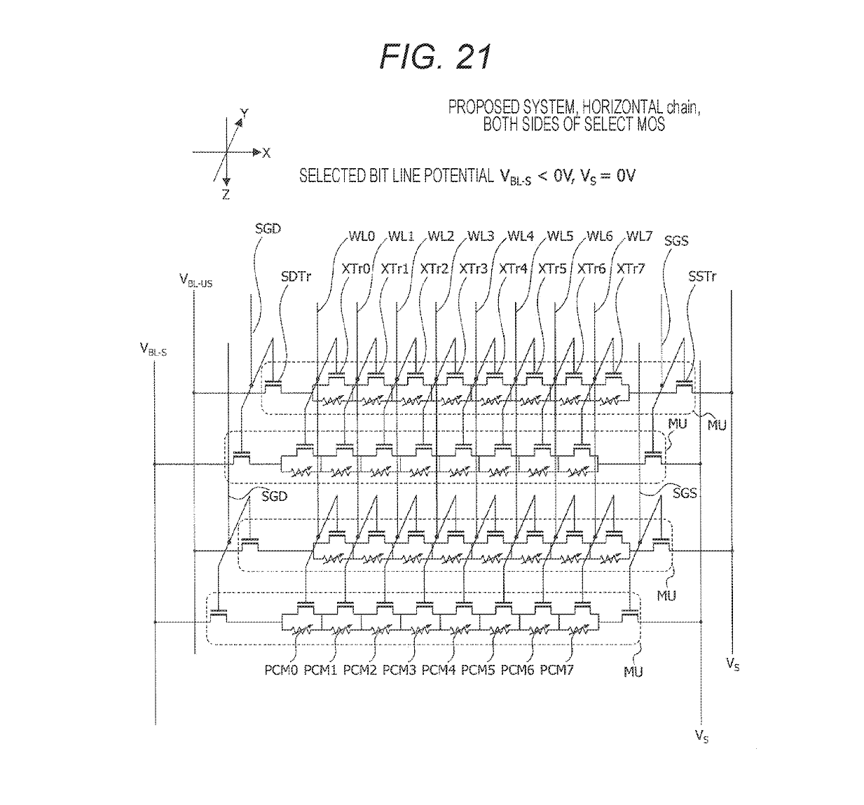

A description will be given regarding an example of a semiconductor storage device which is excellent in endurance characteristics in which the number of rewritable times is large with reference to FIG. 21 in the present embodiment.

A description will not be repeated regarding the configurations attached with the same reference numerals and parts having the same functions as illustrated in FIG. 1 which has been already described.

The memory chain MU is configured to extend in the X direction in the present embodiment. Incidentally, the Z direction is a direction perpendicular to the silicon substrate, and the X direction and the Y direction are perpendicular to the Z direction and perpendicular to each other. In this manner, it is possible to collectively form the memory cells, present in plural in the Z direction, with one-time drilling process, and to reduce the manufacturing cost.

When the memory chain MU is configured to extend in the X direction, it is possible to form the phase change element PCM using a sputter deposition method, which is used to manufacture a DVD (Digital Versatile Disc) without using a CVD method, and there is an advantage that a development period can be shortened as there is no need of newly developing a method of forming the phase change element using the CVD method.

A characteristic of the present embodiment is that a source voltage Vs, which is a voltage of one end between voltages of both ends of the memory chain MU is close to the GND potential, and the voltage VBL-S of the other end is a negative voltage which is lower than the GND potential.

In this manner, the source voltage of the X-select transistor XTr becomes 0 V or lower, it is possible to reduce a voltage to be applied to word lines WL0 to WL7, and it is possible to reduce the voltage between the gate and the source to be applied to the X-select transistor XTr of the unselected memory chain MU.

Memory chain select transistors are present at both the ends of the memory chain MU in the present embodiment. One of the memory chain select transistors is indicated by SDTr, and the other is indicated by SSTr. It is possible to perform a part of a select operation by controlling gate voltages of these transistors using signal lines SGD and SGS. When the memory chain select transistors are present at both the ends of the memory chain MU, the inside of the memory chain MU of which the memory chain select transistor is turned off is set in a floating state and is hardly affected by disturbance, and thus, it is possible to realize the highly reliable semiconductor storage device.

Incidentally, the memory chain select transistor has a finite resistance and does not cause the inside of the memory chain to be a complete floating state, and the parasitic capacitance is present in the memory chain, and thus, it is a matter of course that there occurs a problem that the voltage between the gate and the source of the X-select transistor XTr of the unselected memory chain MU increases, and the reliability of the semiconductor storage device decreases only by providing the memory chain select transistors at both the ends of the memory chain MU when the voltage VBL-S is not set to a negative voltage which is lower than the GND potential. That is, it is possible to realize the highly reliable semiconductor storage device by using the voltage VBL-S which is the negative voltage lower than the GND potential even in the configuration that provides the memory chain select transistors at both the ends of the memory chain MU.

Meanwhile, a reason that the source voltage Vs, which is the voltage of one end between the voltages of both ends of the memory chain MU is slightly higher than the GND potential is because a small voltage drop occurs when the current flows between the source wiring and the GND terminal of the semiconductor storage device since the electrical resistance is present therebetween.

### Embodiment 8

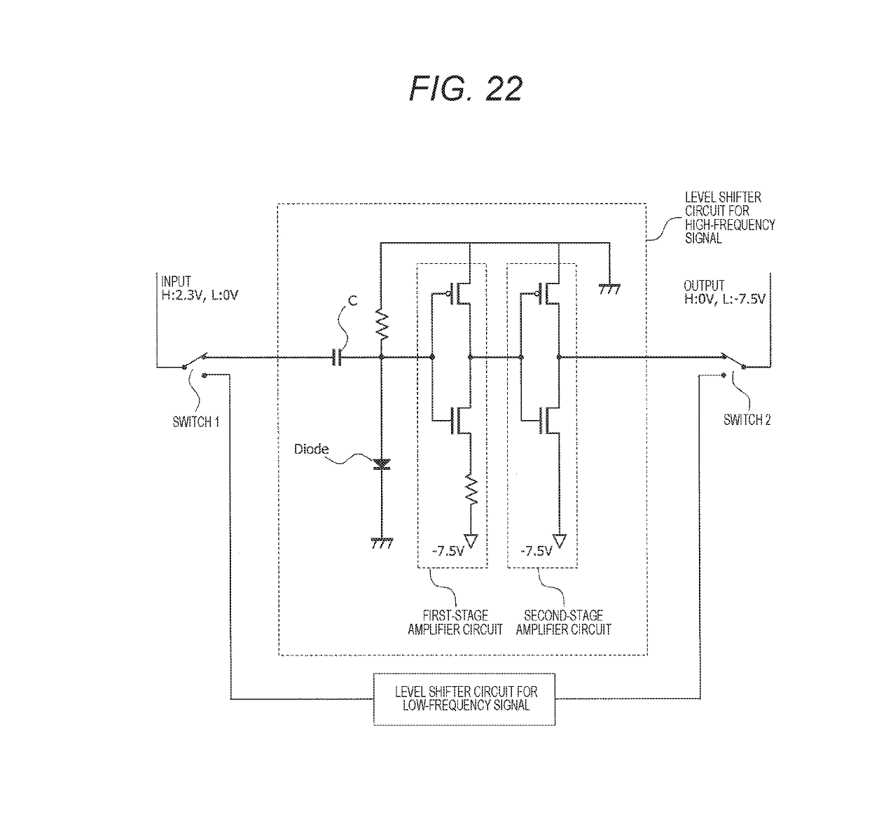

A description will be given regarding an example of a semiconductor storage device which operates at a high speed with reference to FIG. 22 in the present embodiment.

A description will not be repeated regarding the configurations attached with the same reference numerals and parts having the same functions as illustrated in FIG. 1 which has been already described.

A circuit illustrated in FIG. 22 is used as a level shifter circuit in the present embodiment.

One of characteristics of this circuit is that two level shifter circuits including the level shifter circuit for a high-frequency signal and the level shifter circuit for a low-frequency signal are provided, and it is possible to switch a level shifter circuit to be used using a switch 1 and a switch 2. Accordingly, it is possible to select an optimal level shifter circuit in response to a frequency of a signal.

Incidentally, it is desirable to set an interval between wirings to be longer in wirings for the high-frequency signal than in wirings for the low-frequency signal. In this manner, it is possible to reduce the parasitic capacitance between wirings, and to realize the semiconductor storage device that operates at the high speed.

In the phase change element PCM, a write time per a single element is short, for example, 10 nsec, and an erase time or a read time thereof is long, for example, 300 nsec. Thus, it is possible to use the level shifter circuit for the high-frequency signal at the time of write, and to use the level shifter circuit for the low-frequency signal at the time of read or at the time of erase.

In addition, it is desirable to set a signal frequency of the row-system circuit to be lower than a signal frequency of the column-system circuit. For example, a maximum signal frequency of the column-system circuit is 100 MHz, and a maximum signal frequency of the row-system circuit is 500 kHz. In this manner, it is possible to design the circuit such that only a signal of the column-system circuit is transferred at a high speed. It is possible to reduce the circuit area and to realize the semiconductor storage device with the low cost. In this case, it is desirable to use the circuit illustrated in FIG. 22 as the column-system circuit and to use a circuit, as the row-system circuit, in which the switches and the level shifter circuit for the high-frequency signal are eliminated from the circuit of FIG. 22 and only the level shifter circuit for the low-frequency signal is provided. In this manner, it is possible to reduce the circuit area and to realize the semiconductor storage device with the low cost.

The level shifter circuit for the high-frequency signal will be described. This circuit first performs polarity conversion of a signal having a high-voltage side H of 2.3 V and a low-voltage side L of 0 V, which is an input signal, into a signal having a high-voltage side of 0 V and a low-voltage side L of −2.3 V using a capacitance C and a diode Diode. Next, the signals are amplified using the first-stage amplifier circuit and the second-stage amplifier circuit, thereby generating an output signal, that is, a signal having a high-voltage side H of 0 V and a low-voltage side L of −7.5 V.

### Embodiment 9

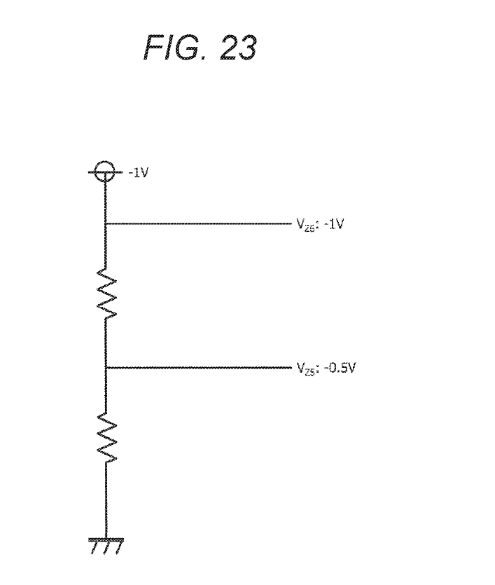

A description will be given regarding an example of a semiconductor storage device that has a small circuit area and can be manufactured with low cost with reference to FIG. 23 in the present embodiment.

A description will not be repeated regarding the configurations attached with the same reference numerals and parts having the same functions as illustrated in FIGS. 1 and 17 which have been already described.

FIG. 23 illustrates potentials VZ5 and VZ6 to be supplied to the Z-select MOS gate electrodes Z5 and Z6 which are parts of the memory array 602. The power-supply voltage of −1 V is directly supplied to the Z-select MOS gate electrode Z6. On the other hand, the potential VZ6 and the GND voltage are connected to the Z-select MOS gate electrode Z5 using two resistances, and a voltage generated in the middle thereof is supplied thereto. It is a matter of course that it is possible to provide a switch so as to supply a voltage only at a part of the time of write and stop the supply of voltage by turning off the switch at the other time.

When such a circuit configuration is used, it is possible to realize the semiconductor storage device that has the small circuit area and that can be manufactured with the low cost.

### REFERENCE SIGNS LIST

601 semiconductor storage device
602 memory array
603 row-system circuit
604 column-system circuit
605 power supply circuit
606 command decoder, control circuit, buffer device
901 Z-select transistor gate electrode
902 interlayer insulating film
903 gate oxide film
904 silicon channel
905 phase change material
906 silicon oxide film
ZTr Z-select transistor
PCM phase change element
XTr X-select transistor
VX X-select line potential
VBL-S selected bit line potential
VBL-US unselected bit line potential
VZ Z-select line potential
MU, MC memory chain
IS write current
IUS unselected memory chain current
VREF reference voltage
VOUTPUT output voltage
X SEL X-select line
XTr X-select transistor
SHFT booster circuit

1. A semiconductor storage device comprising a plurality of memory chains including a plurality of memory cells connected in series, wherein the memory cell is a storage element that performs rewrite using a cell transistor and current, the memory chain has a structure in which the storage elements are connected in parallel, a power-supply voltage and a ground voltage are supplied from an outside, and a voltage to be used for the rewrite of the storage element is lower than the ground voltage.

2. The semiconductor storage device according to claim 1, wherein the storage element is any of a phase change memory, a ReRAM, and an STT-MRAM.

3. The semiconductor storage device according to claim 1, wherein the memory chain includes at least one select element, and the select element and the plurality of memory cells are connected in series.

4. The semiconductor storage device according to claim 3, wherein the select element is a MOSFET or a diode.

5. The semiconductor storage device according to claim 4, wherein the MOSFET is a double-gate type.

6. The semiconductor storage device according to claim 1, wherein the memory chain includes three or more of the memory cells, is provided with a first gate electrode of the cell transistor of a first memory cell, a second gate electrode of the cell transistor of a second memory cell electrically coupled with the first gate electrode through an electrical capacitance, and a third gate electrode of the cell transistor of a third memory cell electrically coupled with the second gate electrode through an electrical capacitance, and applies a voltage to the first gate electrode and the third gate electrode in a state in which the second gate electrode is set in a floating state so as to change a voltage of the second gate electrode.

7. The semiconductor storage device according to claim 1, wherein the memory chain is arranged to be perpendicular to a substrate.

8. The semiconductor storage device according to claim 3, wherein the single select element is provided, is arranged at one side of the memory chain, and has another end being connected to the entire memory chain.

9. The semiconductor storage device according to claim 1, wherein, when rewriting a value of the storage element from “0” to “1” is set as erase, and rewriting a value of the storage element from “1” to “0” is set as write in the rewrite of the storage element, a voltage to be used as a voltage for the write is lower than the ground voltage, and a voltage to be used for the erase is higher than the ground voltage.

10. The semiconductor storage device according to claim 1, wherein a voltage to be used for read is higher than the ground voltage, and a number of signal voltage level conversion circuits is larger than a total number of a row-system circuit and a column-system circuit.

11. The semiconductor storage device according to claim 1, wherein a Z-select gate voltage level is higher at a time of erase than at a time of write, and voltage levels at the time of erase have five or more levels.

12. A semiconductor storage device comprising a plurality of memory chains including one select transistor and a plurality of memory cells connected in series, wherein the select transistor and the plurality of memory cells are connected in series, the memory cell has a structure in which storage elements to perform rewrite using a cell transistor and current are connected in parallel, a voltage pulse is applied to a source line at a time of writing the storage element when a side of the memory chain on which the select transistor is provided is set as a bit line and another side thereof on which the select transistor is not provided is set as the source line, and a second voltage is higher than the first voltage when a voltage of the bit line is set as the first voltage and a voltage of the voltage pulse is set as the second voltage.

13. The semiconductor storage device according to claim 12, wherein the storage element is a phase change memory, and the select transistor is a double-gate MOSFET.

14. A semiconductor storage device comprising a plurality of memory chains including one select transistor and a plurality of memory cells connected in series, wherein the select transistor and the plurality of memory cells are connected in series, the memory cell has a structure in which storage elements to perform rewrite using a cell transistor and current are connected in parallel, a first voltage is lower than a second voltage when a side of the memory chain on which the select transistor is provided is set as a bit line, another side thereof on which the select transistor is not provided is set as a source line, a voltage of the bit line at a time of writing the storage element is set as the first voltage, and a voltage of the source line is set as the second voltage, further a voltage of the source line at a time of reading the storage element is equal to the second voltage, a third voltage is higher than the first voltage when a voltage of the bit line at the time of reading the storage element is set as the third voltage, and
a number of the memory chains connected to the source line is equal to or larger than a number of gate electrodes of the cell transistors connected to one electrode.

15. The semiconductor storage device according to claim 14, wherein the storage element is a phase change memory, and the select transistor is a double-gate MOSFET.
